(19) United States
(12) Patent Application Publication
(10) Pub. No.: US 2012/0249157 A1
(43) Pub. Date: Oct. 4, 2012

(54) TEST APPARATUS

(75) Inventors: Masaaki KOSUGI, Gunma (JP); Kunihiko KAWASAKI, Saitama (JP)

(73) Assignee: ADVANTEST CORPORATION, Tokyo (JP)

(21) Appl. No.: 13/410,264

(22) Filed: Mar. 1, 2012

(30) Foreign Application Priority Data
Apr. 4, 2011 (JP) 2011-082454

(51) Int. Cl. G01R 31/02

(52) U.S. Cl. 324/537

(57) ABSTRACT

Provided is a test apparatus that tests a memory under test including a plurality of repair regions for repairing fails in a memory region, the test apparatus comprising a testing section that sequentially tests each of a plurality of portions of the memory region of the memory under test; a repair solution memory that stores a repair solution indicating which repair region replaces a fail portion of the memory under test; and an updating section that, during testing, in response to a new fail portion being detected by the testing section, updates the repair solution stored in the repair solution memory to be a repair solution that also repairs the newly detected fail portion.

### BACKGROUND

1. Technical Field

The present invention relates to a test apparatus.

2. Related Art

A memory test apparatus that tests a semiconductor memory includes an address fail memory (AFM) having an address space identical to that of the memory under test. The memory test apparatus compares the data output from the memory under test to an expected value, in order to judge pass/fail of the cell from which the data was read. If the cell is a fail, the memory test apparatus writes fail data indicating that this cell is a fail to an address in the AFM corresponding to the fail cell. Furthermore, after the testing is finished, the memory test apparatus reads the fail data written to the AFM and calculates a repair solution for replacing the fail cells in the memory under test with repair regions.
Patent Document 1: Japanese Patent Application Publication No. 2007-85813
Patent Document 2: Japanese Patent Application Publication No. 2007-80422

However, since the memory test apparatus stores fail data of the memory under test for each address, the memory test apparatus must include an address fail memory with a large capacity. Furthermore, the memory under test includes column repair regions for repairing fail cells in column units and row repair regions for repairing fail cells in row units, for example. When testing such a memory under test, the memory test apparatus must select an optimal repair solution from all combinations of column repair regions and row repair regions, and therefore a large circuit is necessary to perform this complicated calculation.

If there are too many fail cells within the memory under test, then it may be impossible to repair all of the fail cells using the repair regions. In such a case, the memory test apparatus must output a result indicating that repair is impossible. However, in order to output the result that repair is impossible, the memory test apparatus must confirm that repair cannot be achieved with any combinations of the column repair regions and the row repair regions, and this requires a long computation time and high computation cost.

### SUMMARY

Therefore, it is an object of an aspect of the innovations herein to provide a test apparatus, which is capable of overcoming the above drawbacks accompanying the related art. The above and other objects can be achieved by combinations described in the independent claims. According to a first aspect related to the innovations herein, provided is a test apparatus that tests a memory under test including a plurality of repair regions for repairing fails in a memory region, the test apparatus comprising a testing section that sequentially tests each of a plurality of portions of the memory region of the memory under test; a repair solution memory that stores a repair solution indicating which repair region replaces a fail portion of the memory under test; and an updating section that, during testing, in response to a new fail portion being detected by the testing section, updates the repair solution stored in the repair solution memory to be a repair solution that also repairs the newly detected fail portion.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a test apparatus 10 according to an embodiment of the present invention, along with a memory under test 200.

FIG. 2 shows an exemplary configuration of the memory under test 200.

FIG. 3 shows a repair solution in a case where the cell at the address (3, 1) in the memory under test 200 is a fail.

FIG. 4 shows an exemplary repair solution for repairing a plurality of fail cells in the memory under test 200.

FIG. 5 shows a combination of types of repair regions for repairing a plurality of fail cells in a memory under test 200 having two column repair regions 220 and two row repair regions 230.

FIG. 6 shows exemplary repair solutions stored in the repair solution memory 30 and unrepairable flags stored in the flag storage section 34.

FIG. 7 shows a process flow of the test apparatus 10 when new fail cells occur.

FIG. 8 shows an exemplary procedure for updating the repair solutions performed by the updating section 32.

FIG. 9 shows an exemplary procedure for updating the repair solutions performed following the procedure of FIG. 8.

FIG. 10 shows an exemplary procedure for updating the repair solutions performed following the procedure of FIG. 9.

FIG. 11 shows exemplary processing performed by a test apparatus 10 according to a first modification.

FIG. 12 shows a process flow of a test apparatus 10 according to a second modification.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

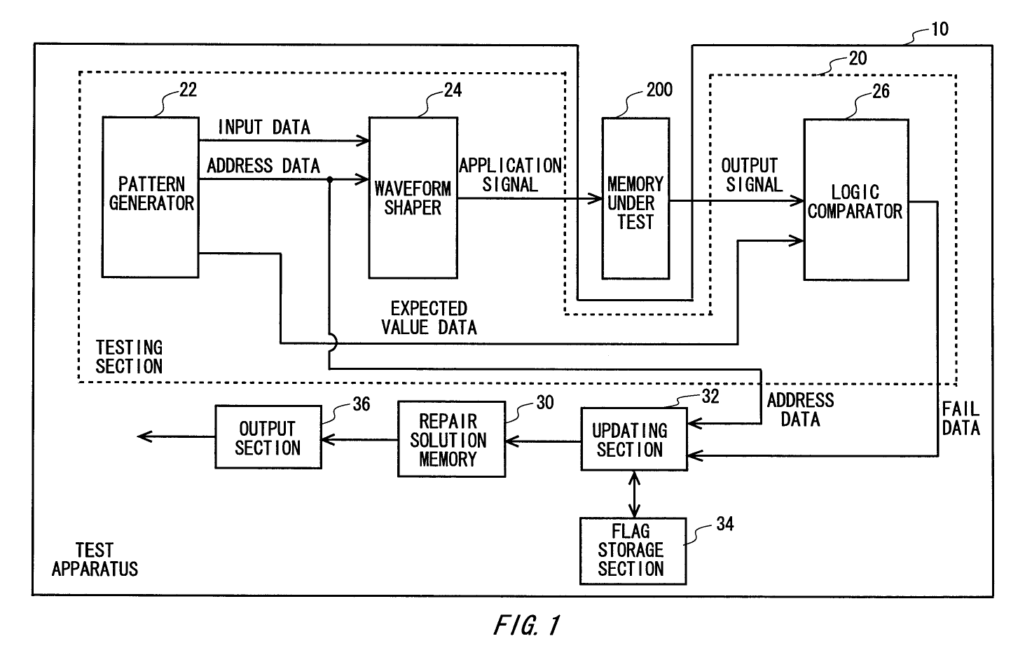

FIG. 1 shows a configuration of a test apparatus 10 according to an embodiment of the present invention, along with a memory under test 200. The test apparatus 10 of the present embodiment tests the memory under test 200.

The memory under test 200 includes a plurality of repair regions for repairing fails within a memory region. More specifically, the memory under test 200 includes a plurality of each type of a plurality of repair regions having different repair ranges in the memory region.

The test apparatus 10 tests each portion, e.g. each cell, in the memory region of the memory under test 200, and detects fail portions, e.g. fail cells, to which data cannot be correctly written or from which data cannot be correctly read. Furthermore, the test apparatus 10 generates repair solutions indicating how the detected fail portions can be replaced with the repair regions to achieve successful repair.

The test apparatus 10 includes a testing section 20, a repair solution memory 30, an updating section 32, a flag storage section 34, and an output section 36. The testing section 20 sequentially tests each portion in the memory region of the memory under test 200 and detects fail portions. Every time a fail portion is detected, the testing section 20 outputs fail data indicating that a fail has been detected and address data indicating the address of the fail portion.

The testing section 20 includes a pattern generator 22, a waveform shaper 24, and a logical comparator 26. The pattern generator 22 generates input data and address data of the memory under test 200 according to a reference clock, and supplies the generated data to the waveform shaper 24. The pattern generator 22 generates expected value data to be compared to the output data of the memory under test 200, and supplies the logical comparator 26 with the expected value data.

The waveform shaper 24 forms an application signal based on the input data and address data, and supplies the application signal to the memory under test 200. The logical comparator 26 compares the output data from the memory under test 200 to the expected value data, for each cell (bit) of the memory under test 200. The logical comparator 26 outputs fail data when the output data does not match the expected value data.

The repair solution memory 30 stores repair solutions for repairing the fail portions of the memory under test 200. More specifically, the repair solution memory 30 stores a plurality of repair solutions for different combinations of fail portions that are repaired by the different types of repair regions in the memory under test 200.

During testing of the memory under test 200 by the testing section 20, the updating section 32 receives from the testing section 20 fail data indicating that a new fail portion, e.g. fail cell, has been detected and address data indicating the address of the fail portion. In response to the testing section 20 detecting a new fail portion, the updating section 32 updates the repair solutions stored in the repair solution memory 30 to be repair solutions that repair the new fail portion.

More specifically, in response to the detection of a new fail portion, the updating section 32 updates each of the repair solutions stored in the repair solution memory 30 to be a repair solution in which the new fail portion and the one or more fail portions that have been replaced according to the previous repair solution are each replaced with one of the plurality of types of repair regions. In this case, the updating section 32 updates the repair solutions stored in the repair solution memory 30 such that each repair solution uses a different combination of repair regions to repair the fail portions.

The flag storage section 34 stores an unrepairable flag indicating that the memory under test 200 cannot be repaired, for each of the repair solutions stored in the repair solution memory 30. When a new fail portion is detected, the updating section 32 stores an unrepairable flag in the flag storage section 34 in association with each repair solution that cannot repair the new fail portions even after the repair solutions stored in the repair solution memory 30 are updated.

After the testing, the repair solution memory 30 outputs to an analyzing computer, for example, at least one of the repair solutions stored in the repair solution memory 30. More specifically, after testing, the repair solution memory 30 outputs at least one of the repair solutions for which an unrepairable flag is not stored, from among the repair solutions stored in the repair solution memory 30.

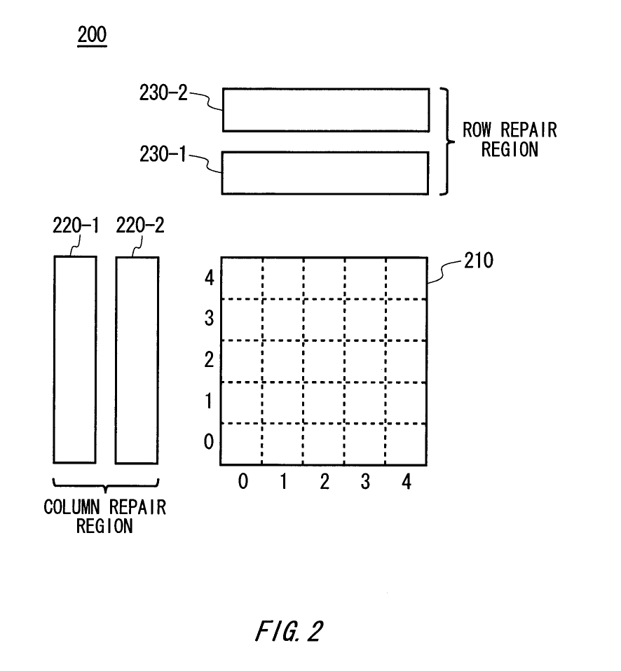

FIG. 2 shows an exemplary configuration of the memory under test 200. The memory under test 200 may include a memory region 210, a plurality of column repair regions 220, and a plurality of row repair regions 230, for example.

The memory region 210 includes a plurality of cells arranged in a rectangle. Each cell arranged in the rectangle has allocated thereto an address indicating the position of the cell in a row direction and a column direction.

Each column repair region 220 is used as a storage region for replacing a plurality of cells arranged in a column in the memory region 210. Therefore, each column repair region 220 can repair en masse a plurality of cells arranged in a column in the memory region 210.

Each row repair region 230 is used as a storage region for replacing a plurality of cells arranged in a row in the memory region 210. Therefore, each row repair region 230 can repair en masse a plurality of cells arranged in a row in the memory region 210. In this way, the memory under test 200 includes a plurality of types of repair regions having different repair ranges in the memory region 210.

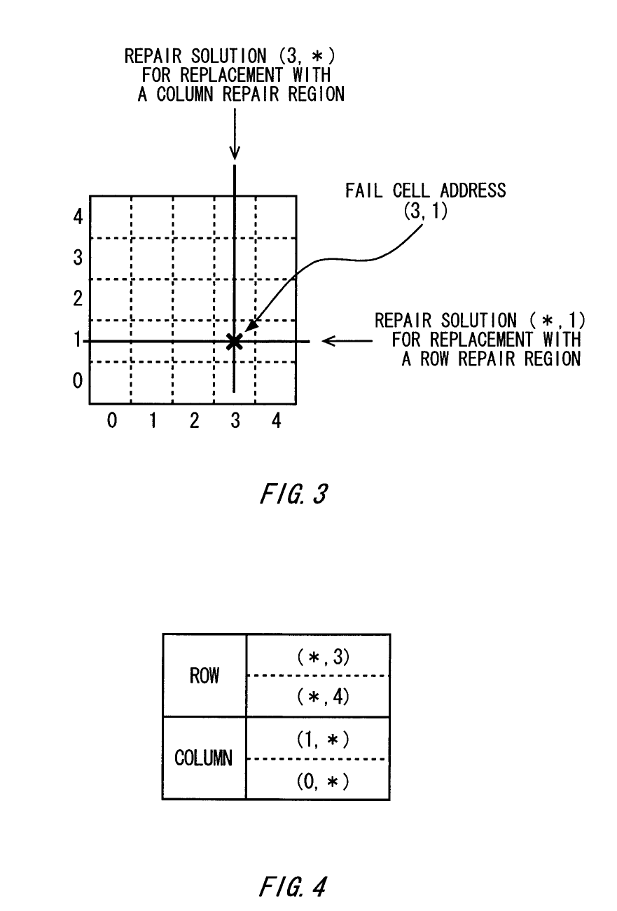

FIG. 3 shows a repair solution in a case where the cell at the address (3, 1) in the memory under test 200 is a fail. When a fail cell occurs in a memory under test 200 including column repair regions 220 and row repair regions 230, the fail cell is replaced by a column repair region 220 or a row repair region 230.

In the present embodiment, (X, Y) represents the address of a cell with a column address X and a row address Y. A repair solution in which the cell at the address (X, Y) is replaced by a column repair region 220 is represented by (X, *). A repair solution in which the cell at the address (X, Y) is replaced by a row repair region 230 is represented by (*, Y).

Accordingly, the repair solution for replacing the fail cell at the address (3, 1) with a column repair region 220, for example, is (3, *). As another example, the repair solution for replacing the fail cell at the address (3, 1) with a row repair region 230 is (*, 1).

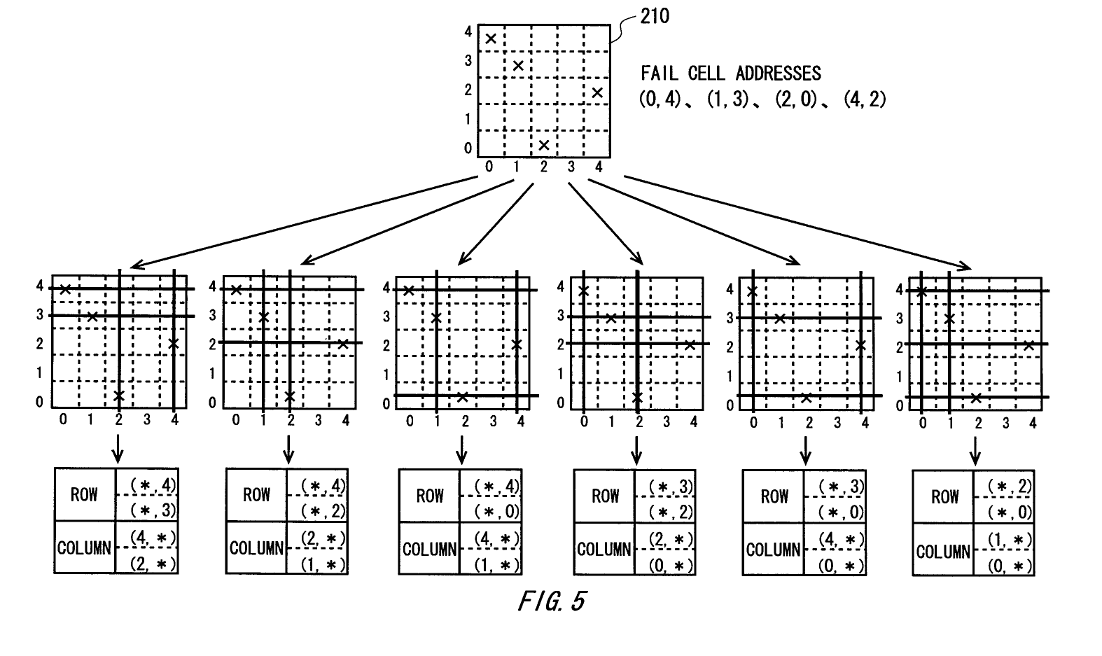

FIG. 4 shows an exemplary repair solution for repairing a plurality of fail cells in the memory under test 200. The repair solution for repairing the plurality of fail cells in the memory under test 200 is represented by a combination of individual repair solutions for performing individual repair using a plurality of repair regions.

For example, if the memory under test 200 includes two column repair regions 220 and two row repair regions 230, the repair solution for repairing the plurality of fail cells in the memory under test 200 is a combination of two individual repair solutions indicating cells to be respectively repaired by the two column repair regions 220 and two individual repair solutions indicating cells to be respectively repaired by the two row repair regions 230. In the present embodiment, the repair solution for repairing the plurality of fail cells in the memory under test 200 is presented as individual repair solutions for each of the repair regions, for example, as shown in FIG. 4.

FIG. 5 shows a combination of types of repair regions for repairing a plurality of fail cells in a memory under test 200 having two column repair regions 220 and two row repair regions 230. For example, in the memory under test 200 having two column repair regions 220 and two row repair regions 230, there are four fail cells that all have different column addresses and different row addresses from each other. In this case, there are six combinations of types of repair regions (combinations of column repair regions 220 and row repair regions 230) for repairing the four fail cells.

For example, if the memory under test 200 includes n types of repair regions having different repair ranges, where n is an integer greater than 1, when there is a total of r repair regions in the memory under test 200, where r is at least 3, the number S of combinations of types of repair regions for repairing r fail cells is expressed as shown below in Expression 1.

S=ₙCᵣ Expression 1:

When the memory under test 200 includes a plurality of types of repair regions in this way, there are a plurality of combinations of types of repair regions for repairing fail cells in the memory under test 200.

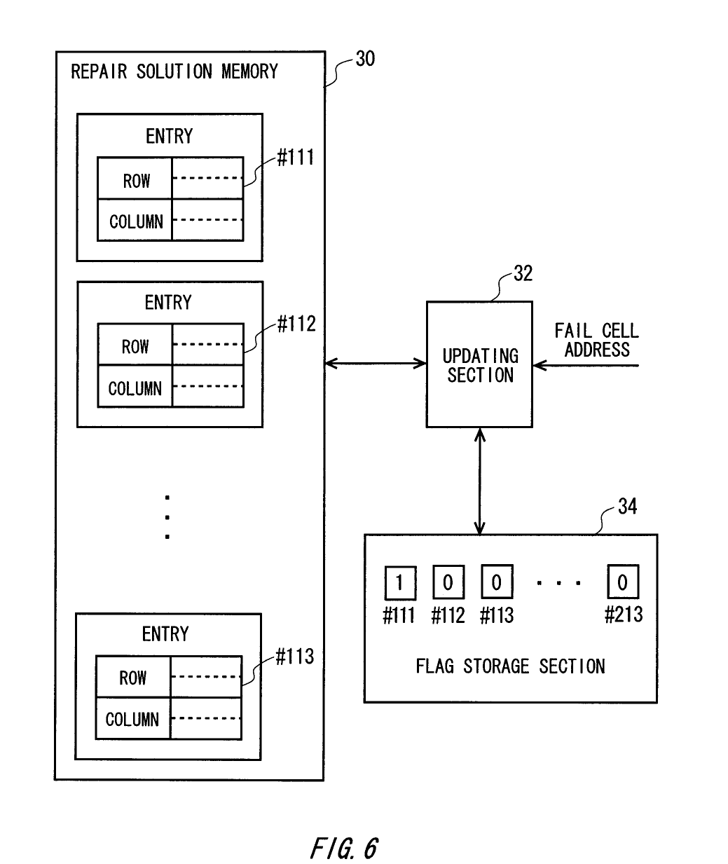

FIG. 6 shows exemplary repair solutions stored in the repair solution memory 30 and unrepairable flags stored in the flag storage section 34. The repair solution memory 30 includes a plurality of entries that each store one repair solution.

In the repair solution memory 30, the number of entries storing repair solutions is preferably equal to the number of combinations of repair region types in the memory under test 200. In other words, the repair solution memory 30 preferably includes S entries, where S is the number of combinations indicated by Expression 1. For example, when the memory under test 200 includes two column repair regions 220 and two row repair regions 230, the repair solution memory 30 preferably includes six entries.

The flag storage section 34 can store an unrepairable flag corresponding to each repair solution stored in the repair solution memory 30. As an example, the flag storage section 34 may store a value of 0 for a repair solution that can repair the memory under test 200, and may store a value of 1 indicating an unrepairable flag for a repair solution that cannot repair the memory under test 200. The flag storage section 34 may be a register that is accessed by the updating section 32, for example.

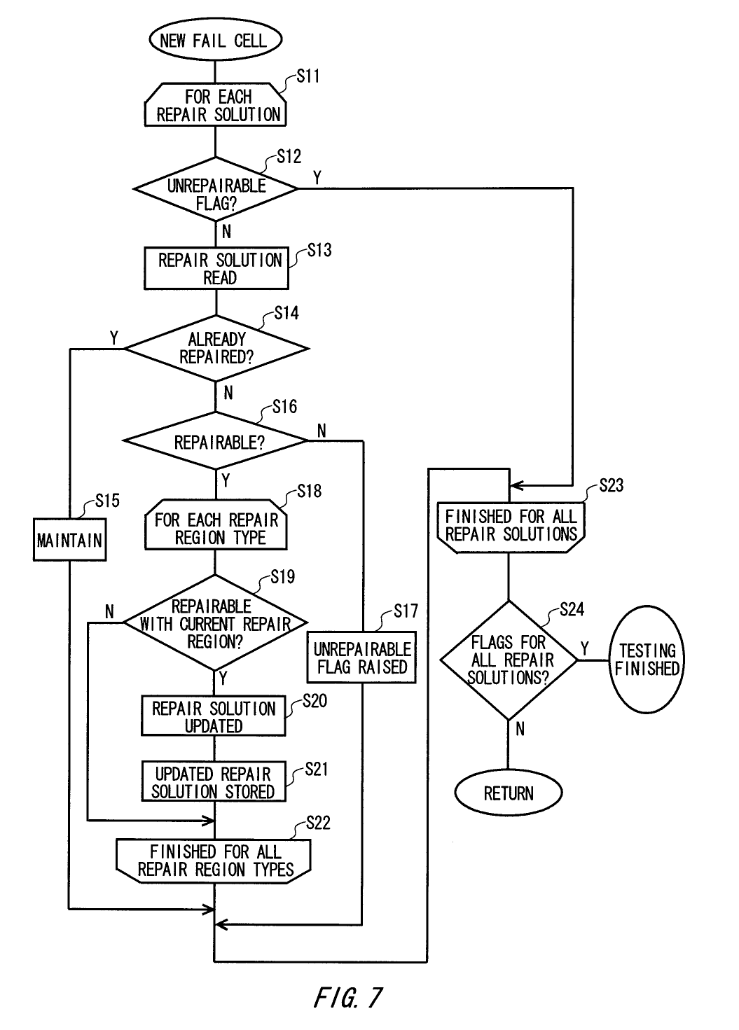

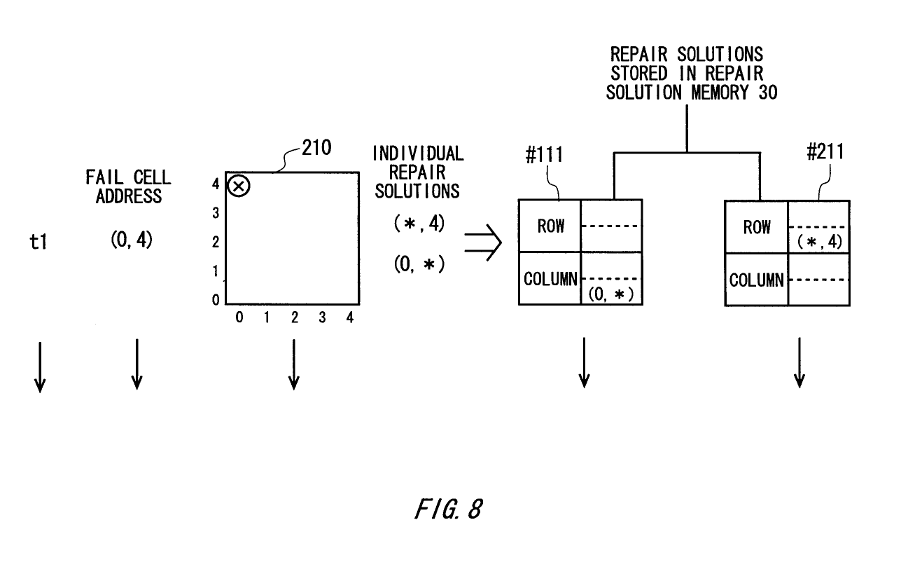

FIG. 7 shows a process flow of the test apparatus 10 when new fail cells occur. During testing of the memory under test 200, the test apparatus 10 performs steps S11 to S24 each time a new fail cell is detected.

The updating section 32 repeats the processes of steps S12 to S22 (the process loop between steps S11 and S23) for each repair solution stored in the repair solution memory 30, in response to a new fail cell being detected. Immediately after testing is begun, there are no repair solutions stored in the repair solution memory 30. Therefore, when the first fail cell is detected, the updating section 32 performs the series of steps from S18 to S22 once.

At step S12, the updating section 32 determines whether an unrepairable flag is stored in association with the repair solution. If the updating section 32 determines that an unrepairable flag is stored in association with the repair solution (the “Yes” of S12), the processing moves to step S23. If the updating section 32 determines that an unrepairable flag is not stored in association with the repair solution (the “No” of S12), the processing moves to step S13.

At step S13, the updating section 32 reads the repair solution from the corresponding entry of the repair solution memory 30. Next, at step S14, the updating section 32 determines whether the new fail cell is already repaired by this repair solution. In other words, at step S14, the updating section 32 determines whether the repair solution already replaces the new fail cell with one of the repair regions, e.g. one of the column repair regions 220 and row repair regions 230.

If the repair solution already repairs the new fail cell, i.e. if the repair solution already replaces with new fail cell with one of the repair regions (the “Yes” of step S14), the updating section 32 moves the processing to step S15. At step S15, the updating section 32 maintains the repair solution. In other words, the updating section 32 does not change the repair solution. When the process of step S15 ends, the updating section 32 moves the processing to step S23.

If the repair solution does not repair the new fail cell, i.e. if the repair solution does not replace the new fail cell with one of the repair regions (the “No” of step S14), the updating section 32 moves the processing to step S16. At step S16, the updating section 32 determines whether the repair solution can additionally repair the new fail cell. In other words, the updating section 32 determines whether the repair solution can further replace the new fail cell with at least one of the types of repair regions, e.g. with at least one of the column repair regions 220 or the row repair regions 230.

If the repair solution cannot repair the new fail cell (the “No” of step S16), the updating section 32 moves the processing to step S17. At step S17, the updating section 32 stores an unrepairable flag in the flag storage section 34 in association with the repair solution. When the process of step S17 ends, the updating section 32 moves the processing to step S23.

If the repair solution can repair the new fail cell (the “Yes” of step S16), the updating section 32 repeatedly performs the processes of steps S19 to S21 (the process loop of steps S18 to S22) for each type of repair region, e.g. for the column repair regions 220 and the row repair regions 230.

At step S19, the updating section 32 judges whether the repair solution can repair the new fail cell by the addition of a repair region, e.g. a column repair region 220 or a row repair region 230. In other words, the updating section 32 determines whether the repair solution can replace the new fail cell by adding this repair region, e.g. the column repair region 220 or the row repair region 230.

If the repair solution cannot repair the new fail cell using this repair region (the “No” of step S19), the updating section 32 moves the processing to step S22. If the repair solution can repair the new fail cell using this repair region (the “Yes” of step S19), the updating section 32 moves the processing to step S20. In the case of the first fail cell detected during testing, the updating section 32 moves the processing to step S20 without making the determination at step S19.

At step S20, the updating section 32 updates the repair solution to replace the new fail portion with the repair region, e.g. the column repair region 220 or the row repair region 230, in addition to the fail cells already replaced by this repair solution. In this way, the updating section 32 can generate a repair solution for repairing all of the fail cells detected from when the testing was begun to the present time. In the case of the first fail cell detected during testing, at step S20, the updating section 32 generates repair solutions that replace only the first detected fail cell with repair regions.

Next, at step S21, the updating section 32 writes the updated repair solution to the entry of the repair solution memory 30. In this case, in the first writing process in the process loop of steps S18 to S22 (the first performance of step S21), the updating section 32 writes the updated repair solution over the data in the entry from which the repair solution was read at step S13. From the second writing process in the process loop of steps S18 to S22 and onward (the second performance of step S21 and onward), the updating section 32 writes the updated repair solution in an empty entry that is separate from the entry from which the repair solution was read at step S13.

In the case of the first fail cell detected during testing, at step S21, the updating section 32 writes the updated repair solution in an empty entry even for the first writing process in the process loop of steps S18 to S22. When the process of step S21 ends, the updating section 32 moves the processing to step S22.

At step S22, the updating section 32 determines whether the process of steps S19 to S21 has been performed for all of the types of repair regions. If this process has yet to be performed for all of the types of repair regions, the updating section 32 returns the processing to step S19 and performs processing for another type of repair region (steps S19 and S22). If the process of steps S19 to S21 has been performed for all of the types of repair regions, the updating section 32 causes the process to exit the loop of steps S18 to S22 and proceed to step S23.

At step S23, the updating section 32 determines whether the process of steps S12 to S22 has been performed for all of the repair solutions stored in the repair solution memory 30. If there is a repair solution stored in the repair solution memory 30 for which the process of steps S12 to S22 has not been performed, the updating section 32 returns the processing to step S12 and performs the process of steps S12 to S22 for the repair solution that has not undergone this process. If this process has been performed for all of the repair solutions stored in the repair solution memory 30, the updating section 32 causes the processing to exit the loop of steps S11 to S23 and proceed to step S24.

At step S24, the updating section 32 determines whether an unrepairable flag is stored in the flag storage section 34 for all of the repair solutions stored in the repair solution memory 30. If an unrepairable flag is stored in the flag storage section 34 for all of the repair solutions stored in the repair solution memory 30 (the “Yes” of step S24), the updating section 32 informs the testing section 20 of this and the process flow ends. When the testing section 20 receives the notification from the updating section 32 that an unrepairable flag is stored for all of the repair solutions stored in the repair solution memory 30, the testing section 20 ends testing of the memory under test 200.

If an unrepairable flag is not stored in the flag storage section 34 for at least one of the repair solutions stored in the repair solution memory 30 (the “No” of step S24), the updating section 32 exits the process flow and suspends processing until the next new fail cell is detected.

In the manner described above, the test apparatus 10 can store repair solutions without storing the fail data of the memory under test 200 for each address. Therefore, the test apparatus 10 can decrease the amount of memory used.

Since the test apparatus 10 updates the repair solutions in real time each time a new fail cell is detected, a large circuit is not needed to analyze the repair solutions, allowing the test apparatus 10 to have a simple configuration. Furthermore, since there is no calculation time after testing, the test apparatus 10 can perform testing with high throughput. Yet further, the test apparatus 10 can output a result indicating that repair is impossible during testing, and therefore pointless computation time is avoided. In addition, by outputting the result indicating that repair is impossible during testing, the test apparatus 10 can stop the test midway through for a memory under test 200 that has too many fail cells to be repaired, and can therefore decrease the testing cost.

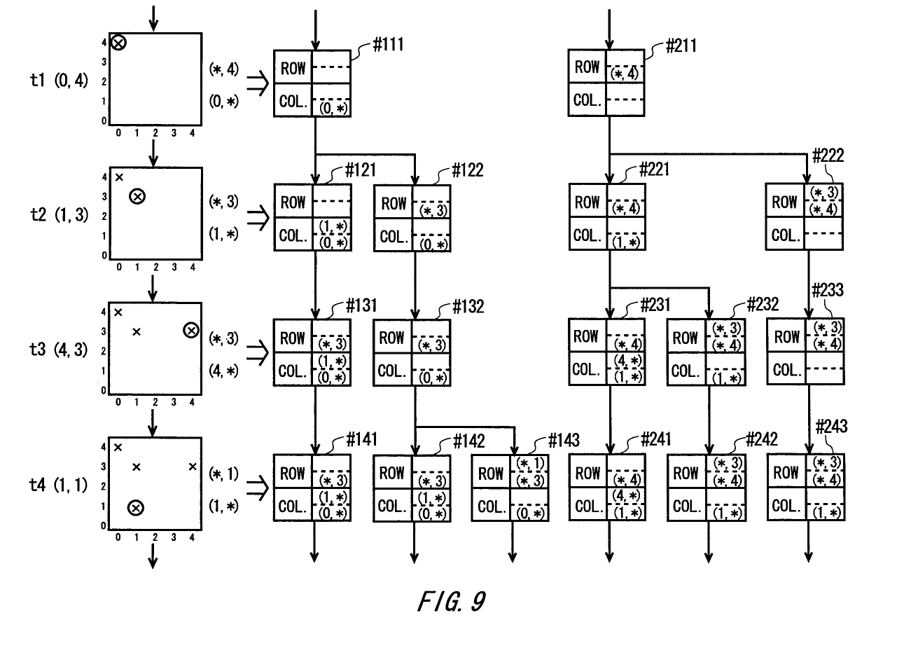

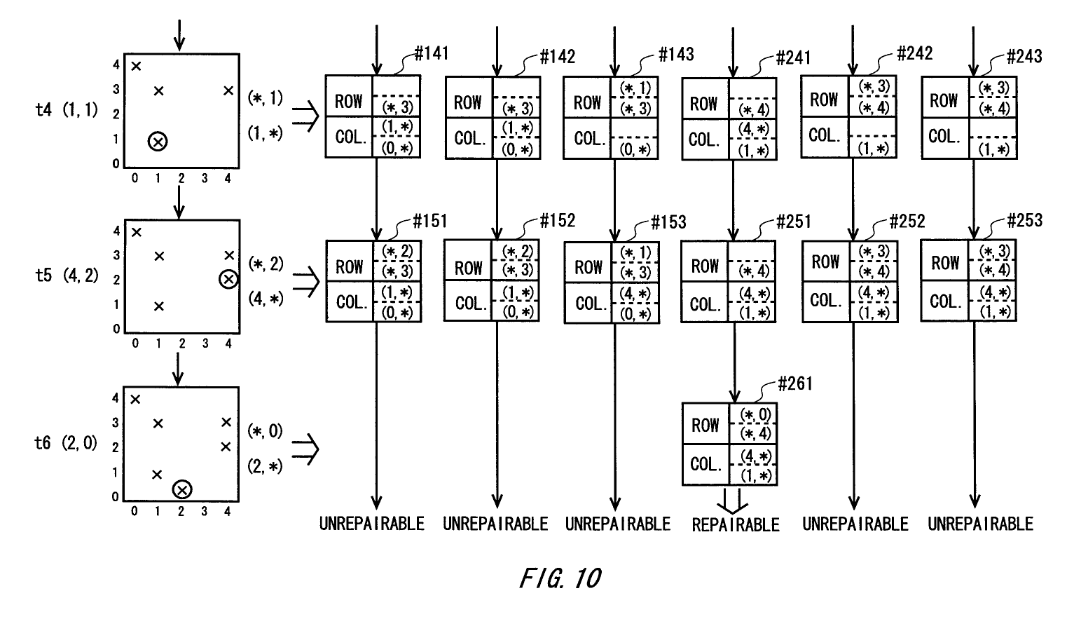

FIG. 8 shows an exemplary procedure for updating the repair solutions performed by the updating section 32. FIG. 9 shows an exemplary procedure for updating the repair solutions performed following the procedure of FIG. 8. FIG. 10 shows an exemplary procedure for updating the repair solutions performed following the procedure of FIG. 9.

FIGS. 8 to 10 show an exemplary procedure for updating the repair solutions in a case where the memory under test 200 being tested includes a memory region 210 having five columns and five rows, two column repair regions 220, and two row repair regions 230. FIGS. 8 to 10 show a procedure for updating the repair solutions in a case where fail cells occur in the addresses (0, 4), (1, 3), (4, 3), (1, 1), (4, 2), and (2, 0) in the stated order.

First, as shown by t1 in FIG. 8, when the first fail cell (0, 4) is detected, the updating section 32 generates repair solution #111 in which is recorded the individual repair solution (0, *) for replacing the address (0, 4) with a column repair region 220. Furthermore, the updating section 32 generates repair solution #211 in which is recorded the individual repair solution (*, 4) for replacing the address (0, 4) with a row repair region 230. The updating section 32 then stores these two repair solutions #111 and #211 in the updating section 32.

Next, as shown by t2 in FIG. 9, when the second fail cell (1, 3) is detected, the updating section 32 updates the two repair solutions #111 and #211 stored in the repair solution memory 30 in the following manner.

The updating section 32 generates repair solution #121 by adding the individual repair solution (1, *), which replaces the address (1, 3) with a column repair region 220, to repair solution #111. The updating section 32 generates repair solution #122 by adding the individual repair solution (*, 3), which replaces the address (1, 3) with a row repair region 230, to repair solution #111.

Furthermore, the updating section 32 generates repair solution #221 by adding the individual repair solution (1, *) to repair solution #211. The updating section 32 generates repair solution #222 by adding the individual repair solution (*, 3) to repair solution #211. The updating section 32 then stores the four updated repair solutions #121, #122, #221, and #222 in the updating section 32.

Next, as shown by t3 in FIG. 9, when the third fail cell (4, 3) is detected, the updating section 32 updates the four repair solutions #121, #122, #221, and #222 stored in the repair solution memory 30 in the following manner.

The updating section 32 generates repair solution #131 by adding the individual repair solution (*, 3), which replaces the address (4, 3) with a row repair region 230, to repair solution #121. Repair solution #121 cannot repair the new fail cell using a column repair region 220. Accordingly, when the third fail cell (4, 3) is detected, the updating section 32 does not update repair solution #121 to be a repair solution in which the new fail cell is replaced by a column repair region 220.

Furthermore, repair solution 122 repairs (*, 3) using a row repair region 230, and therefore already repairs the address (4, 3). Accordingly, when the third fail cell (4, 3) is detected, the updating section 32 causes repair solution #132 to be the same as repair solution #122.

The updating section 32 generates repair solution #231 by adding the individual repair solution (4, *), which replaces the address (4, 3) with a column repair region 220, to repair solution #221. The updating section 32 generates repair solution #232 by adding the individual repair solution (*, 3) to repair solution #221.

Repair solution #222 already repairs the address (4, 3). Accordingly, when the third fail cell (4, 3) is detected, the updating section 32 causes repair solution #233 to be the same as repair solution #222. The updating section 32 then saves these five updated repair solutions #131, #132, #231, #232, and #233 in the updating section 32.

Next, as shown by t4 in FIG. 9, when the fourth fail cell (1, 1) is detected, the updating section 32 updates the five repair solutions #131, #132, #231, #232, and #233 stored in the repair solution memory 30 in the following manner.

Repair solution #131 already repairs address (1, 1). Accordingly, when the fourth fail cell (1, 1) is detected, the updating section 32 causes repair solution #141 to be the same as repair solution #131.

The updating section 32 generates repair solution #142 by adding the individual repair solution (1, *), which replaces the address (1, 1) with a column repair region 220, to repair solution #132. The updating section 32 generates repair solution #143 by adding the individual repair solution (*, 1), which replaces the address (1, 1) with a row repair region 230, to repair solution #132.

Repair solution #231 already repairs the address (1, 1). Accordingly, when the fourth fail cell (1, 1) is detected, the updating section 32 causes repair solution #241 to be the same as repair solution #231.

Repair solution #232 already repairs the address (1, 1). Accordingly, when the fourth fail cell (1, 1) is detected, the updating section 32 causes repair solution #242 to be the same as repair solution #232.

The updating section 32 generates repair solution #243 by adding the individual repair solution (1, *) to repair solution #233. Repair solution #233 cannot repair the new fail cell by using a row repair region 230. Accordingly, when the fourth fail cell (1, 1) is detected, the updating section 32 does not update repair solution #233 to be a repair solution in which the new fail cell is replaced with a row repair region 230. The updating section 32 then stores the six updated repair solutions #141, #142, #143, #241, #242, and #243 in the updating section 32.

Next, as shown by t5 in FIG. 10, when the fifth fail cell (4, 2) is detected, the updating section 32 updates the six repair solutions #141, #142, #143, #241, #242, and #243 stored in the repair solution memory 30 in the following manner.

The updating section 32 generates repair solution #151 by adding the individual repair solution (*, 2), which replaces the address (4, 2) with a row repair region 230, to repair solution #141. The updating section 32 generates repair solution #152 by adding the individual repair solution (*, 2) to repair solution #142. The updating section 32 generates repair solution #153 by adding the individual repair solution (4, *), which replaces the address (4, 2) with a column repair region 220, to repair solution #143.

Repair solutions #141 and #142 cannot repair the new fail cell using a column repair region 220. Accordingly, when the fifth fail cell (4, 2) is detected, the updating section 32 does not update repair solutions #141 and #142 to be repair solutions in which the new fail cell is replaced by a column repair region 220.

Repair solution #241 already repairs the address (4, 2). Accordingly, when the fifth fail cell (4, 2) is detected, the updating section 32 causes repair solution #251 to be the same as repair solution #241. The updating section 32 generates repair solution #252 by adding the individual repair solution (4, *) to repair solution #242. The updating section 32 generates repair solution #253 by adding the individual repair solution (4, *) to repair solution #243.

Repair solutions #143, #242, and #243 cannot repair the new fail cell using a row repair region 230. Accordingly, when the fifth fail cell (4, 2) is detected, the updating section 32 does not update repair solutions #143, #242, and #243 to be repair solutions in which the new fail cell is replaced by a row repair region 230. The updating section 32 then stores the six updated repair solutions #151, #152, #153, #251, #252, and #253 in the updating section 32.

Next, as shown by t6 in FIG. 10, when the sixth fail cell (2, 0) is detected, the updating section 32 updates the six repair solutions #151, #152, #153, #251, #252, and #253 stored in the repair solution memory 30 in the following manner.

Repair solutions #151, #152, #153, #162, and #163 already use all of the repair regions to repair the fail cells. Accordingly, when the sixth fail cell (2, 0) is detected, the updating section 32 does not update repair solutions #151, #152, #153, #162, and #163 to be repair solutions in which the new fail cell is replaced by a repair region. The updating section 32 then stores an unrepairable flag in the flag storage section 34 corresponding to each of repair solutions #151, #152, #153, #162, and #163.

Repair solution #251 has the freedom to repair the new fail cell with a row repair region 230. Therefore, the updating section 32 generates repair solution #261 by adding the individual solution (*, 0), which replaces the address (2, 0) with a row repair region 230, to repair solution #251. The updating section 32 then stores the remaining possible repair solution #261 in the updating section 32.

In the manner described above, the test apparatus 10 can update the repair solutions in real time every time a new fail cell is detected. Furthermore, the test apparatus 10 can store unrepairable flags in association with repair solutions that do not achieve repair during testing.

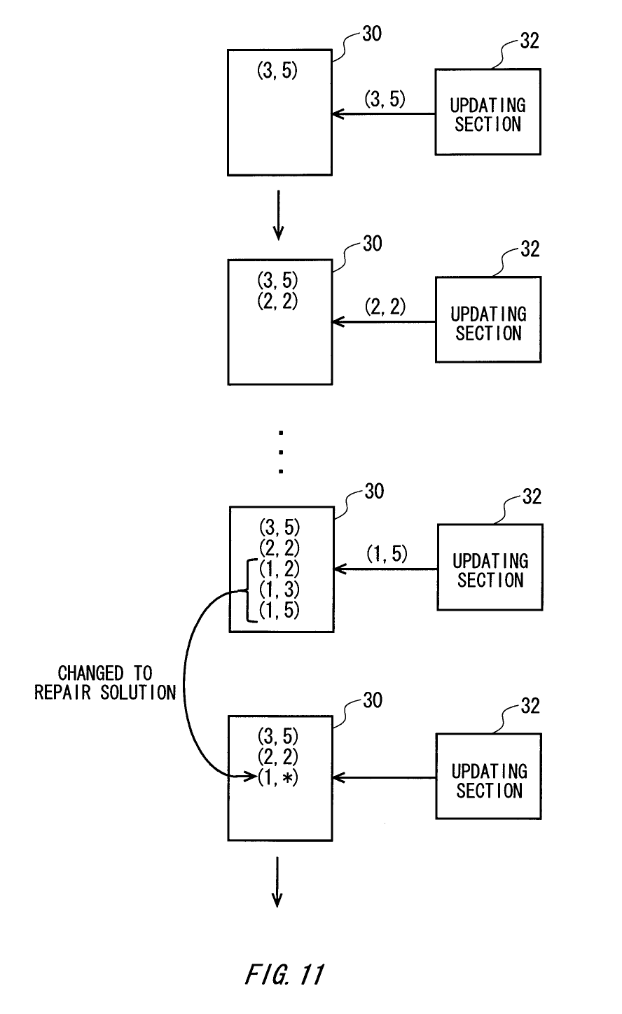

FIG. 11 shows exemplary processing performed by a test apparatus 10 according to a first modification. The test apparatus 10 of the present modification adopts substantially the same function and configuration as the test apparatus 10 of the present embodiment described in relation to FIGS. 1 to 10, and therefore components having the same function and configuration are given the same reference numerals and the following description includes only differing points.

After testing is begun, the updating section 32 of the first modification sequentially stores the addresses of fail cells, instead of repair solutions, in the repair solution memory 30. During testing, the updating section 32 changes the fail cell addresses stored in the repair solution memory 30 into repair solutions

For example, during testing, when a region to be repaired, e.g. a column or a row, is detected, the updating section 32 replaces the fail cell addresses included in this region with a repair solution that repairs this region. More specifically, if the memory under test 200 includes two column repair regions 220, when three fail cells occur in one column in the memory region 210, it is determined that these three fail cells must be repaired by a column repair region 220. When the addresses of these three fail cells are stored in the repair solution memory 30, the updating section 32 changes the addresses of these three fail cells into one repair solution.

The test apparatus 10 according to the first modification can reduce the amount of computation after testing, when there are a small number of fail cells and it is more efficient to directly store the fail addresses in the memory, for example. Furthermore, after a prescribed time has passed, instead of storing the fail cell addresses in the repair solution memory 30, the updating section 32 may store the repair solutions in the repair solution memory 30 using the same method as described in relation to FIGS. 1 to 10.

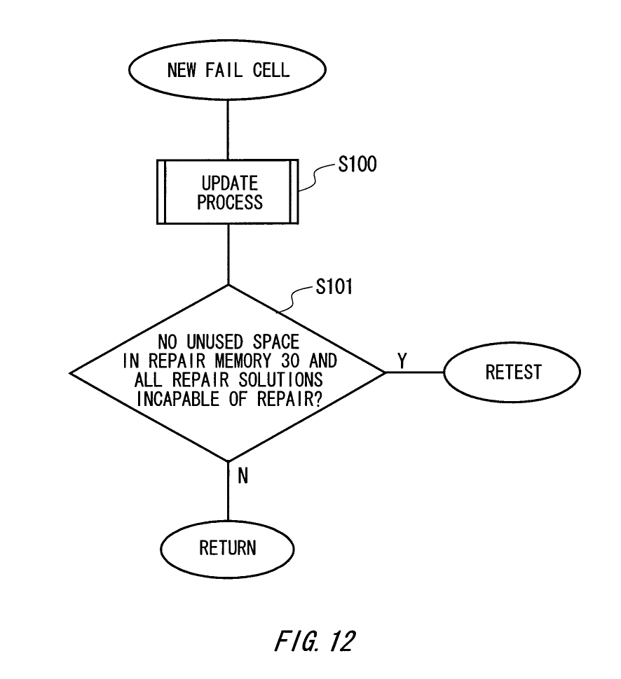

FIG. 12 shows a process flow of a test apparatus 10 according to a second modification. The test apparatus 10 according to the present modification adopts substantially the same function and configuration as the test apparatus 10 of the present embodiment described in relation to FIGS. 1 to 10, and therefore components having the same function and configuration are given the same reference numerals and the following description includes only differing points.

The test apparatus 10 of the second modification includes a repair solution memory 30 with lower capacity than the repair solution memory 30 of the test apparatus 10 of the present embodiment described in relation to FIGS. 1 to 10. In other words, in the repair solution memory 30 in the second modification, the number of entries for storing repair solutions is less than the number of combinations for repairing fail portions that can be repaired by the plurality of types of repair regions of the memory under test 200.

For example, if the memory under test 200 includes two column repair regions 220 and two row repair regions 230, the fail cells can be replaced by six combinations of column repair regions 220 and row repair regions 230. Accordingly, the repair solution memory 30 preferably includes six entries to store at least these six repair solutions. The repair solution memory 30 of the second modification, however, includes less than six entries.

When a new fail cell is detected by the testing section 20, the updating section 32 of the second modification performs the repair solution update process of steps S11 to S24 shown in FIG. 7 (S100). When the process of step S100 ends, the updating section 32 determines whether there is no remaining unused capacity in the repair solution memory 30 and whether all of the repair solutions stored in the repair solution memory 30 indicate that repair is impossible (S101). In other words, the updating section 32 determines whether there is no remaining unused capacity in the repair solution memory 30 and whether an unrepairable flag is stored in the flag storage section 34 for all of the repair solutions recorded in the repair solution memory 30.

If there is unused capacity in the repair solution memory 30 or if at least one repair solution can achieve repair, the updating section 32 suspends processing until the next fail cell is detected (the “No” of S101). However, when the process of step S100 ends, if there is no unused capacity in the repair solution memory 30 and there is indication that all of the repair solutions stored in the repair solution memory 30 are incapable of achieving repair (the “Yes” of S101), the updating section 32 instructs the testing section 20 to perform testing again. Upon receiving the instructions for a retest, the testing section 20 performs the same test again from the beginning.

When the test is performed again by the testing section 20, the updating section 32 updates the repair solutions stored in the repair solution memory 30 to be combinations of repair regions differing from the combinations of repair regions stored in the repair solution memory 30 that were used as the repair solutions in the previous test to replace the fail portions. For example, the repair solution memory 30 may include a number of entries equal to half of the number of combinations of column repair regions 220 and row repair regions 230 of the memory under test 200.

In this case, in the first test, when the first fail cell is detected, the updating section 32 generates a repair solution that repairs the initial fail with only one of a column repair region 220 and a row repair region 230. Next, when the second and following fail cells are detected, the updating section 32 updates the repair solution that repairs the first fail cell to be repair solutions that also replace the new fail cells with column repair regions 220 and row repair regions 230.

In the second test, when the first fail cell is detected, the updating section 32 generates a repair solution that repairs the first fail cell using whichever of the column repair region 220 and the row repair region 230 was not used for repair when the first fail cell was detected in the first test. Next, when the second and following fail cells are detected, the updating section 32 updates the repair solution that repairs the first fail cell to be repair solutions that also replace the new fail cells with column repair regions 220 and row repair regions 230.

If all of the repair solutions are incapable of achieving repair even after a prescribed number of retests, the updating section 32 stops the testing of the memory under test 200 and judges the memory under test 200 to be a fail. The test apparatus 10 according to the second modification can use a repair solution memory 30 with a lower capacity. Furthermore, since there is no need for retesting if there is a low number of fail cells in the memory under test 200, the testing time is not increased when there is a low number of fail cells in the memory under test 200.

The updating section 32 may count the number of detected fail cells during a period from when testing is begun to when it is determined that the memory under test 200 cannot be repaired by any of the repair solutions stored in the repair solution memory 30. In this case, the updating section 32 estimates the number of fail cells in the memory under test 200 based on the number of counted fail cells and the period from when testing is begun to when it is determined that the memory under test 200 cannot be repaired by any of the repair solutions stored in the repair solution memory 30.

The updating section 32 then predicts whether the memory under test 200 can by repaired by retesting, based on the estimated number, and may perform retesting if it is predicted that repair can be achieved. As a result, when it is predicted that the memory under test 200 cannot be repaired, the updating section 32 can shorten the testing time by not performing a retest.

In the second modification, the memory under test 200 may include a repair block that repairs a block unit that is a portion of the memory region 210. When it is determined in the first test that the memory under test 200 cannot be repaired, this updating section 32 may replace a block in which the number of fail cells is greater than or equal to a predetermined value with the repair block before performing the second test. As a result, the updating section 32 can decrease the number of fail cells detected in the second test, thereby increasing the chance of being able to repair the memory under test 200 in the second test.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a memory under test including a plurality of repair regions for repairing fails in a memory region, the test apparatus comprising:
a testing section that sequentially tests each of a plurality of portions of the memory region of the memory under test;
a repair solution memory that stores a repair solution indicating which repair region replaces a fail portion of the memory under test; and
an updating section that, during testing, in response to a new fail portion being detected by the testing section, updates the repair solution stored in the repair solution memory to be a repair solution that also repairs the newly detected fail portion.

2. The test apparatus according to claim 1, wherein
the repair solution memory includes a plurality of types of repair regions having different repair ranges in the memory region, and
the repair solution memory stores a plurality of repair solutions that include different combinations of fail portions repaired by the plurality of types of repair regions.

3. The test apparatus according to claim 2, wherein
in response to the detection of a new fail portion, the updating section updates each of the repair solutions stored in the repair solution memory to be at least one repair solution that replaces the new fail portion with one of the plurality of types of repair regions in addition to the fail portion replaced by the pre-updated repair solution.

4. The test apparatus according to claim 3, wherein
in response to the detection of a new fail portion, the updating section determines whether each repair solution stored in the repair solution memory replaces the new fail portion with one of the repair regions, and
when the repair solution does not replace the new fail portion with a repair region, the updating section generates at least one repair solution that also replaces the new fail portion with at least one of the types of repair regions, based on the original repair solution.

5. The test apparatus according to claim 4, wherein
the updating section maintains the repair solution when the repair solution replaces the new fail portion with one of the repair regions.

6. The test apparatus according to claim 5, further comprising a flag storage section that, for each repair solution stored in the repair solution memory, stores an unrepairable flag indicating that the repair solution cannot repair the memory under test, wherein
when a new fail portion is detected, unrepairable flags are stored in the repair solution memory in association with repair solutions stored in the repair solution memory that cannot repair the new fail portions even when updated.

7. The test apparatus according to claim 6, wherein
the testing section stops testing when unrepairable flags are stored for all of the repair solutions stored in the repair solution memory.

8. The test apparatus according to claim 2, further comprising an output section that, after testing, outputs at least one of the repair solutions stored in the repair solution memory.

9. The test apparatus according to claim 2, wherein the repair solution memory includes:
the memory region having a plurality of cells arranged in a rectangle;
a column repair region that is used as a storage region in place of a plurality of cells arranged in a column in the memory region; and
a row repair region that is used as a storage region in place of a plurality of cells arranged in a row in the memory region.

10. The test apparatus according to claim 2, wherein
the repair solution memory includes a number of entries storing the repair solutions that is equal to the number of combinations of the plurality of types of repair regions in the memory under test.

11. The test apparatus according to claim 2, wherein
the repair solution memory includes a number of entries storing the repair solutions that is less than the number of combinations of fail portions repaired by the plurality of types of repair regions,
the testing section performs testing again when the memory under test cannot be repaired by any of the repair solutions stored in the repair solution memory, and
when testing is performed again by the testing section, the updating section updates each of the repair solutions stored in the repair solution memory to be a repair solution that uses a combination of repair regions differing from the combinations of repair regions used to replace the fail portions by the repair solutions stored in the repair solution memory prior to the testing being performed again.

12. The test apparatus according to claim 1, wherein
after testing is begun, the updating section stores addresses of the fail portions in the repair solution memory instead of the repair solutions and, during testing, the updating section changes the addresses of the fail portions stored in the repair solution memory into repair solutions.
